(19) United States
(12) Patent Application Publication
(10) Pub. No.: US 2006/0254754 A1
(43) Pub. Date: Nov. 16, 2006

(54) Panel-type radiating system

(76) Inventor: Jian-Dih Jeng, Lin-Kou (TW)

Correspondence Address: APEX JURIS, PLLC;TRACY M HEIMS, LAKE CITY CENTER, SUITE 410, 12360 LAKE CITY WAY NORTHEAST, SEATTLE, WA, 98125, US

(21) Appl. No.: 11/126,557

(22) Filed: May 11, 2005

(51) Int. Cl. H05K 7/20

(52) U.S. Cl. 165/104.33; 165/80.3; 361/700

(57) ABSTRACT

A panel-type radiating system includes a panel being provided on at least one side with a plurality of fins, and a plurality of heat conducting tubes having a heat-dissipating end and a heat-absorbing end each. The heat-dissipating ends of the heat conducting tubes are connected to the fins, and are located at a level higher than that of the heat-absorbing ends. With these arrangements, the panel-type radiating system is able to provide the maximum radiating effect via a large-area panel and maintain the panel at a uniform temperature.

### FIELD OF THE INVENTION

The present invention relates to a panel-type radiating system, and more particularly to a panel-type radiating system that is able to provide the maximum radiating effect via a large-area panel and maintain the panel at a uniform temperature.

### BACKGROUND OF THE INVENTION

A panel used in an electronic product, such as the panel for a liquid crystal display (LCD) and a light emitting diode (LED) display, normally has a back plate made of an aluminum material, at where most heat produced by the display is gathered. As a result of thermal convection, an upper portion of the back plate has a temperature much higher than that of a lower portion of the back plate. And, most of the commercially available LED backlight module displays include a sideward radiating mechanism. However, the heat source at a central area of the panel has a temperature higher than surrounding areas of the panel, resulting in uneven temperature distribution on the panel to adversely affect the overall quality of the electronic product.

### SUMMARY OF THE INVENTION

A primary object of the present invention is to provide a panel-type radiating system that is able to provide the maximum radiating effect via a large-area panel and maintain the panel at a uniform temperature through particularly arrayed heat conducting tubes, fins with specially designed number, size, and locations, and fans corresponding to the fins.

To achieve the above and other objects, the panel-type radiating system according to the present invention includes a panel being provided on at least one side with a plurality of fins, and a plurality of heat conducting tubes having a heat-dissipating end and a heat-absorbing end each. The heat-dissipating ends of the heat conducting tubes are connected to the fins, and are located at a level higher than that of the heat-absorbing ends.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is a perspective view of a panel-type radiating system according to a first embodiment of the present invention;

FIG. 2 shows heat conducting tubes are serially embedded in one thermal conductive seat included in the panel-type radiating system of the present invention;

FIG. 3 shows a panel-type radiating system according to a second embodiment of the present invention;

FIG. 4 shows a panel-type radiating system according to a third embodiment of the present invention;

FIG. 5 is a sectional view of a panel-type radiating system according to a fourth embodiment of the present invention;

FIG. 6 is a sectional view of a panel-type radiating system according to a fifth embodiment of the present invention;

FIG. 7 is a sectional view of a panel-type radiating system according to a sixth embodiment of the present invention; and

FIG. 8 shows a panel-type radiating system according to a seventh embodiment of the present invention.

### DETAILED DESCRIPTION OF THE PREFERRED EMBODIMENTS

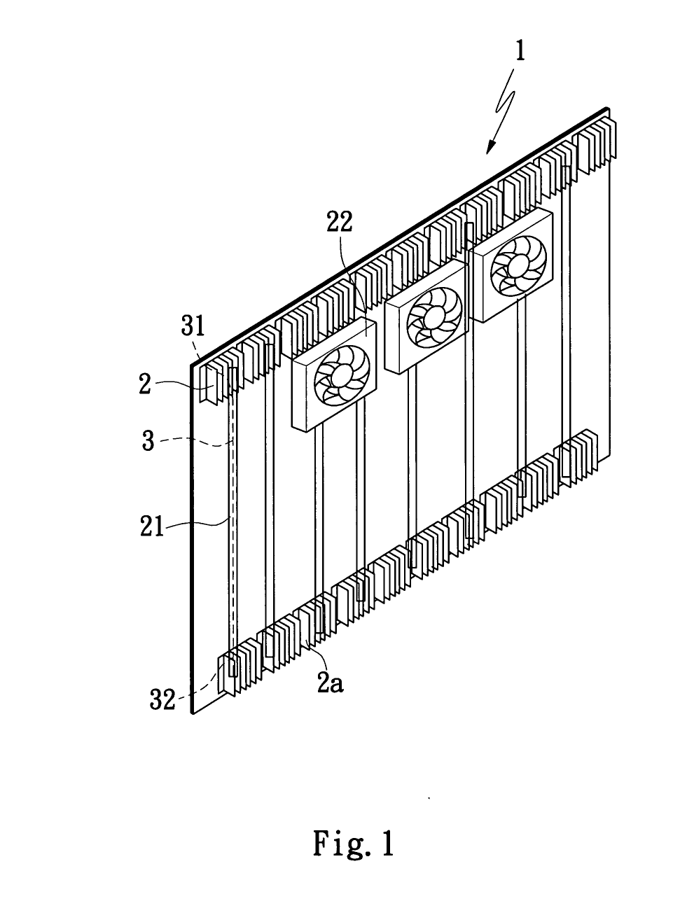

Please refer to FIG. 1 that is a perspective view of a panel-type radiating system according to a first embodiment of the present invention. As shown, the panel-type radiating system includes a panel 1, a plurality of upper and lower fins 2, 2a, and a plurality of heat conducting tubes 3.

The panel 1 may be a planar panel, a perforated panel, a ribbed panel, etc., and is adapted to directly or indirectly receive heat from a plurality of point, line, or surface source of heat. Backlight panels for liquid crystal display (LCD) and light-emitting diode (LED) display are examples of such panel. The panel 1 has a large area to effectively provide the maximum radiating ability and effect while maintains a uniform temperature.

The upper and lower fins 2, 2a are provided on an upper and a lower side of the panel 1, respectively. A plurality of thermal conductive seats 21 are also provided on the panel 1 with two ends connected to the upper and the lower fins 2, 2a, respectively. The thermal conductive seats 21 may be made of a conductive metal material, such as copper, aluminum, etc., or a composite material containing graphite, carbon, etc. A plurality of fans 22 may also be provided on the panel 1 corresponding to the upper fins 2.

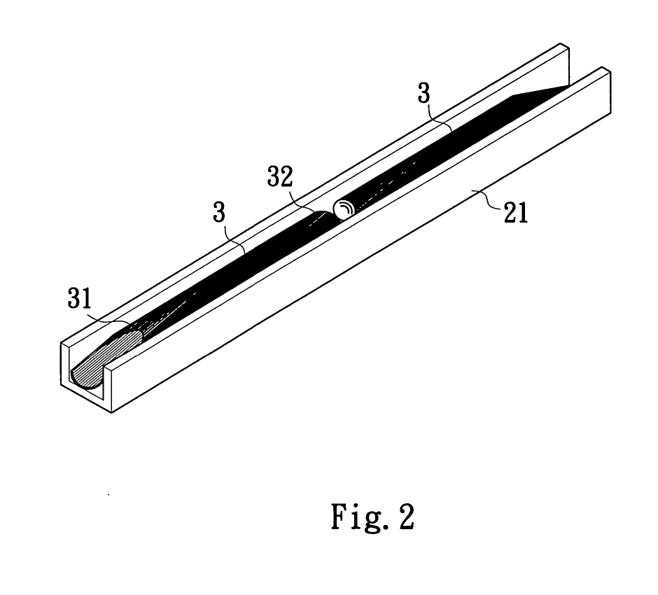

Please refer to FIG. 2. Each of the heat conducting tubes 3 includes a heat-dissipating end 31 and a heat-absorbing end 32. Two or more heat conducting tubes 3 are serially embedded in one thermal conductive seat 21 with the heat-dissipating ends 31 connected to the upper and the lower fins 2, 2a.

In practical use of the present invention, the heat conducting tubes 3 are in contact with the panel 1 to receive heat from the panel 1 and transfer the received heat to the upper and the lower fins 2, 2a. The fans 22 are connected to the upper fins 2 to effectively lower the temperature of the upper fins 2 and thereby increase the heat that can be delivered via the upper fins 2. In an overall design for guiding airflow in the present invention, the fan 22 has an air inlet located at a lower portion thereof, and an air outlet located at an upper portion thereof. Since the lower fins 2a are close to the air inlets of the fans 22, it is not necessary to provide other fans for connecting to the lower fins 2a. In the present invention, the lower fins 2a have an overall area that provides a heat conducting volume about one fourth or less of that of the upper fins 2, and are mainly used to balance the heat source at the lower side of the panel 1. When the upper fins 2 and the fans 22 together provide good heat radiating effect, it is possible to omit the lower fins 2a from the panel 1.

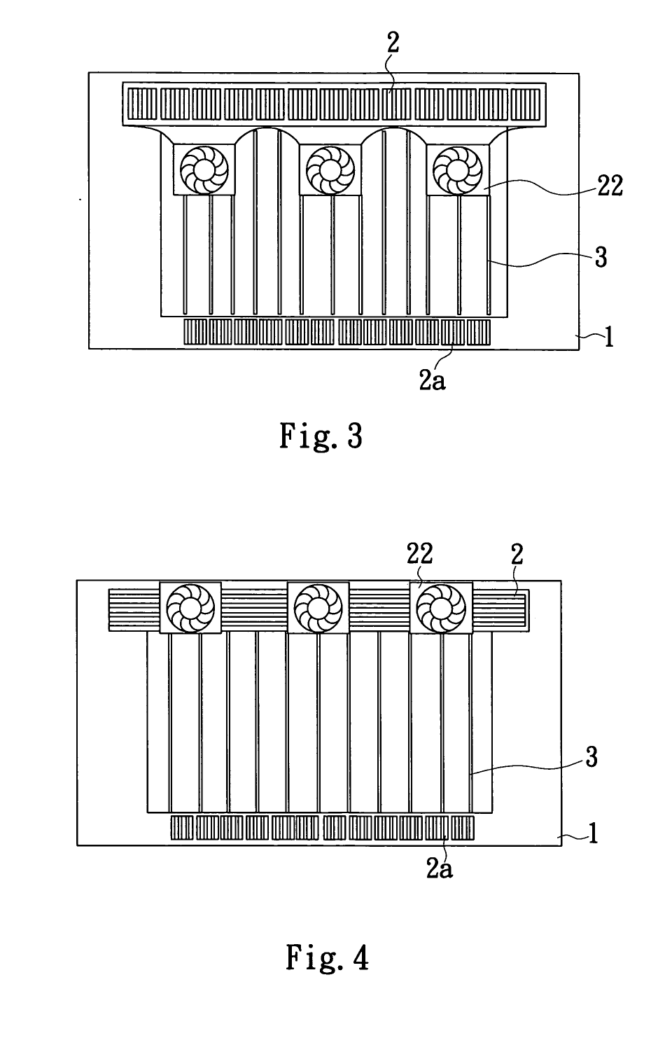

In the present invention, the fans 22 may be located at different positions relative to the upper fins 2 in consideration of the whole space available for use. FIG. 3 shows a panel-type radiating system according to a second embodiment of the present invention, in which the fans 22 are located below the upper fins 2 to produce upward airflows. FIG. 4 shows a panel-type radiating system according to a third embodiment of the present invention, in which the fans 22 are located in front of the upper fins 2 to produce forward airflows. In practical use of the present invention, the second embodiment with fans 22 producing upward airflows provides relatively high heat dissipating effect.

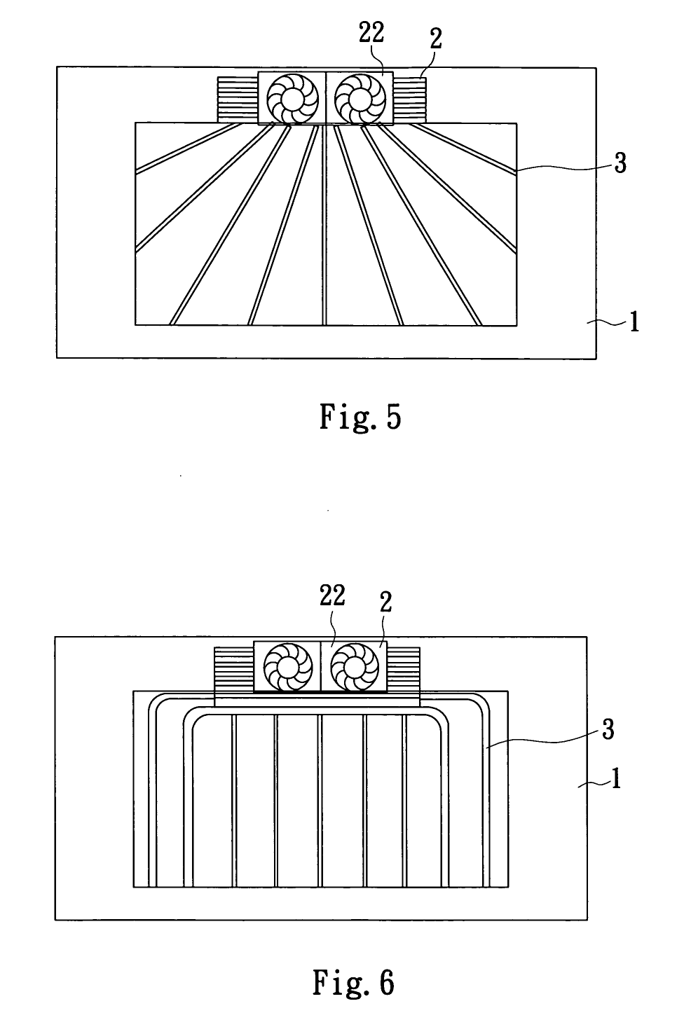

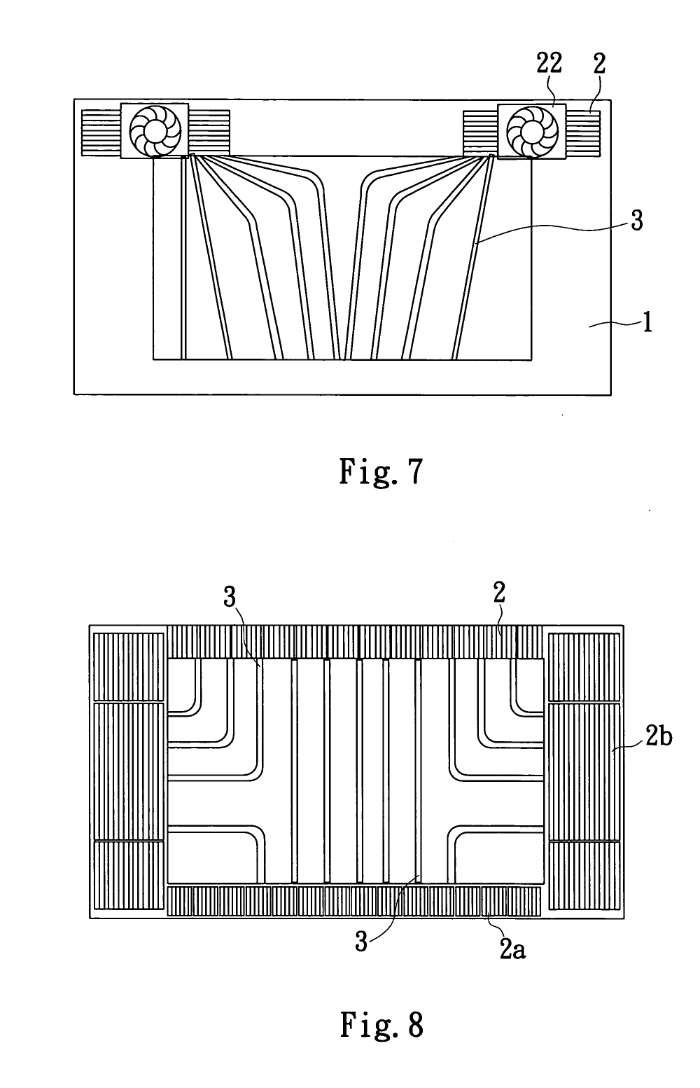

The fans 22 may also be located at different positions relative to the panel 1 in consideration of the arrangement of the heat conducting tubes 3 on the panel 1. FIG. 5 shows a panel-type radiating system according to a fourth embodiment of the present invention, in which the heat conducting tubes 3 are arranged with the heat-dissipating ends 31 gathered at an upper central area of the panel 1. FIG. 6 shows a panel-type radiating system according to a fifth embodiment of the present invention, in which the heat conducting tubes 3 are arranged with the heat-dissipating ends 31 evenly distributed along the upper side of the panel 1. FIG. 7 shows a panel-type radiating system according to a sixth embodiment of the present invention, in which the heat conducting tubes 3 are arranged with the heat-dissipating ends 31 gathered at two upper outer corners of the panel 1.

In the present invention, it is possible to increase the number and the area of radiating fins provided on the panel 1, so as to increase the reliability of the present invention and to minimize the required maintenance thereof. FIG. 8 shows a panel-type radiating system according to a seventh embodiment of the present invention, in which large-area fins 2, 2a, 2b are provided at upper, lower, and two lateral sides of the panel 1 to cooperate with the heat conducting tubes 3 to radiate heat from the panel 1 and keep the panel 1 at a uniform temperature. In this case, the fans 22 may be omitted. In the seventh embodiment, the panel 1 is generally divided into three heat dissipating areas, namely, upper, middle, and lower areas. Most part of heat is radiated from the upper area of the panel 1 while the two lateral sides of the middle area are the second largest heat-radiating areas. Through particularly designed area allocation of fins 2, 2a, 2b and arrangement of heat conducting tubes 3 on the panel 1, desired heat radiation effect and uniform panel temperature may be obtained from the panel-type radiating system of the present invention.

The present invention has been described with some preferred embodiments thereof and it is understood that many changes and modifications in the described embodiments can be carried out without departing from the scope and the spirit of the invention that is intended to be limited only by the appended claims.

What is claimed is:

1. A panel-type radiating system, comprising:
a panel being provided on at least one side with a plurality of fins; and
a plurality of heat conducting tubes having a heat-dissipating end and a heat-absorbing end each, said heat-dissipating ends being connected to said fins provided on said panel and located at a level higher than that of said heat-absorbing ends.

2. The panel-type radiating system as claimed in claim 1, wherein said panel has a plurality of thermal conductive seats provided thereon; said thermal conductive seats being connecting to said fins, and said heat conducting tubes being embedded in said heat conductive seats.

3. The panel-type radiating system as claimed in claim 2, wherein said thermal conductive seats are made of a conductive metal material selected from the group consisting of copper, aluminum, etc.

4. The panel-type radiating system as claimed in claim 2, wherein said thermal conductive seats are made of a composite material containing graphite, carbon, etc.

5. The panel-type radiating system as claimed in claim 1, wherein said heat conducting tubes maybe serially connected in said thermal conductive seats when said panel has a relatively large size.

6. The panel-type radiating system as claimed in claim 1, wherein said heat conducting tubes are arranged on said panel in different patterns selected from the group consisting of longitudinally extended patterns, radially extended patterns, etc., so that said heat-dissipating ends and said heat-absorbing ends are so located and directed to evenly deliver heat from said panel.

7. The panel-type radiating system as claimed in claim 1, further comprising a plurality of fans provided on said panel corresponding to said fins.

8. The panel-type radiating system as claimed in claim 7, wherein said fans are located below said fins to produce upward airflows.

9. The panel-type radiating system as claimed in claim 7, wherein said fans are located in front of said fins to produce forward airflows.
